(19) United States
(12) Patent Application Publication
(10) Pub. No.: US 2024/0120275 A1
(43) Pub. Date: Apr. 11, 2024

(54) METAL WIRING OF SEMICONDUCTOR DEVICE

(71) Applicant: SK hynix Inc., Icheon-si (KR)

(72) Inventors: Seong Ho CHOI, Icheon-si (KR); Chang Man SON, Icheon-si (KR)

(21) Appl. No.: 18/310,300

(22) Filed: May 1, 2023

(30) Foreign Application Priority Data
Oct. 11, 2022 (KR) 10-2022-0129557

(51) Int. Cl. H01L 23/528; H01L 21/768; H01L 23/532

(52) U.S. Cl. CPC H01L 23/528; H01L 21/76828; H01L 23/53209

(57) ABSTRACT

A metal wiring of a semiconductor device may include: a first metal line disposed in a first metal layer, and defined with an opening in a first region; and a contact metal passing through a dielectric layer under the first metal layer adjacent to the opening and connected to the first metal line around the opening.

### CROSS-REFERENCE TO RELATED APPLICATION

The present application claims priority under 35 U.S.C. § 119(a) to Korean Patent Application No. 10-2022-0129557 filed in the Korean Intellectual Property Office on Oct. 11, 2022, which is incorporated herein by reference in its entirety.

### BACKGROUND

### 1. Technical Field

Various embodiments generally relate to a semiconductor technology, and more particularly, to a metal wiring of a semiconductor device that leads to the reduction of defects.

### 2. Related Art

Various materials such as aluminum (Al), tungsten (W), titanium (Ti) and copper (Cu) are being used as materials for metal wiring in a semiconductor device. Among them, aluminum has many advantages and has been used for longest, but more recently copper, with its low resistance, has been widely used.

In order for a wiring to properly perform its role as a conductor, a certain minimum width needs to be maintained. However, semiconductor device structures trend towards higher density and function trends toward high speed operations, the width of the wiring narrows, resulting in an increase in defects in which the wiring does not properly transfer current or is disconnected.

One of causes of wiring defects is a migration phenomenon in which metal particles move out of place and migrate due to heat and high temperatures. When the migration amount of metal particles increases in this way, metal particles decrease at specific portions in wiring and voids can form where metal particles decrease. The voids may make the wiring thinner, thereby increasing wiring resistance and causing a disconnection of the wiring.

### SUMMARY

Various embodiments are directed to a metal wiring of a semiconductor device capable of reducing defects.

In an embodiment, a metal wiring of a semiconductor device may include: a first metal line disposed in a first metal layer, and having an opening in a first region; and a contact metal passing through a dielectric layer under the first metal layer adjacent to the opening and connected to the first metal line around the opening. The first region may be a region where heat is concentrated.

In an embodiment, a metal wiring of a semiconductor device may include: a first metal line disposed in a first metal layer and disconnected in a first region; and a contact metal passing through a first dielectric layer under the first metal layer, crossing the first metal line in the first region in a vertical direction, and connecting disconnected ends of to the first metal line.

In an embodiment, a metal wiring of a semiconductor device may include: a first metal line disposed in a first metal layer, disconnected in a region where the first metal line does not overlap a metal line of a second metal layer in a vertical direction, and divided into a first part and a second part; and a contact metal connecting the first part and the second part, wherein a first distance in the vertical direction between the second metal layer and the contact metal is greater than a second distance between the second metal layer and the first metal layer.

### BRIEF DESCRIPTION OF THE DRAWINGS

FIG. 1 is a cross-sectional view illustrating an example of a metal wiring of a semiconductor device related to the disclosed technology.

FIG. 2 is a plan view illustrating another example of a metal wiring of a semiconductor device related to the disclosed technology.

FIG. 3 is a plan view illustrating still another example of a metal wiring of a semiconductor device related to the disclosed technology.

FIG. 4 is a cross-sectional view illustrating a metal wiring of a semiconductor device according to an embodiment of the disclosure.

FIG. 5 is a plan view illustrating a metal wiring of a semiconductor device according to another embodiment of the disclosure.

FIG. 6 is a cross-sectional view taken along the line I-I′ of FIG. 5.

FIG. 7 is a plan view illustrating a metal wiring of a semiconductor device according to another embodiment of the disclosure.

FIG. 8 is a cross-sectional view taken along the line II-II′ of FIG. 7.

FIG. 9 is a block diagram of a memory card including a metal wiring according to an embodiment of the disclosure.

FIG. 10 is a block diagram of an electronic system to which a semiconductor device including a metal wiring according to an embodiment of the disclosure is applied.

### DETAILED DESCRIPTION

Advantages and features of the disclosure and methods to achieve them will become apparent from the descriptions of exemplary embodiments herein below with reference to the accompanying drawings. However, the present disclosure is not limited to the exemplary embodiments disclosed herein but may be implemented in various different ways. The exemplary embodiments are provided for making the disclosure of the present disclosure thorough and for fully conveying the scope of the present disclosure to those skilled in the art.

Since the figures, dimensions, ratios, angles, numbers of elements given in the drawings to describe embodiments of the disclosure are merely illustrative, the present disclosure is not limited to the illustrated matters. Throughout the specification, like reference numerals refer to like components. In describing the disclosure, when it is determined that the detailed description of the related art may obscure the gist of the disclosure, the detailed description thereof will be omitted. It is to be noticed that the terms “comprising,” “having,” “including” and so on, used in the description and claims, should not be interpreted as being restricted to the means listed thereafter unless specifically stated otherwise. Where an indefinite or definite article, e.g., “a,” “an” or “the,” is used when referring to a singular noun, the article may include a plural of that noun unless specifically stated otherwise. In interpreting elements in embodiments of the disclosure, they should be interpreted as including error margins even without explicit statements.

Also, in describing the components of the disclosure, there may be used terms such as first, second, A, B, (a), and (b). These are solely for the purpose of differentiating one component from another component but do not limit the substances, order, sequence or number of the components. Also, components in embodiments of the disclosure are not limited by these terms. These terms are used to merely distinguish one component from another component. Accordingly, as used herein, a first component may be a second component within the technical spirit of the disclosure.

If a component is described as “connected,” “coupled” or “linked” to another component, it may mean that the component is not only directly “connected,” “coupled” or “linked” but also is indirectly “connected,” “coupled” or “linked” via a third component. In describing positional relationship, such as “an element A on an element B,” “an element A above an element B,” “an element A below an element Bi” and “an element A next to an element B,” one or more other elements may be disposed between the elements A and B unless the term “directly” or “immediately” is explicitly used.

Features of various exemplary embodiments of the disclosure may be coupled, combined or separated partially or totally. Technically various interactions and operations are possible. Various exemplary embodiments can be practiced individually or in combination.

Hereinafter, various examples of embodiments of the disclosed technology will be described in detail with reference to the accompanying drawings.

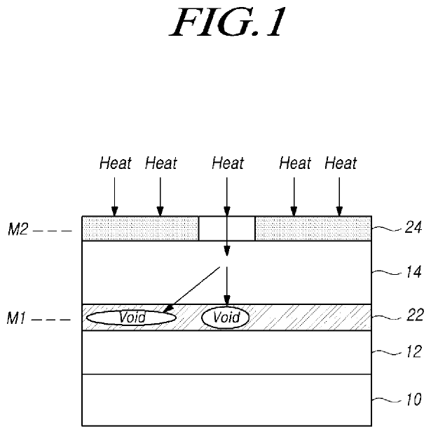

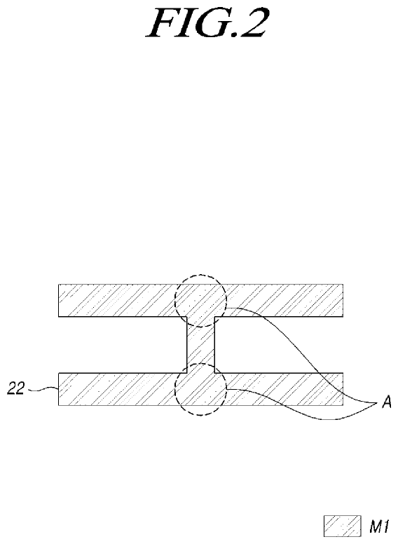

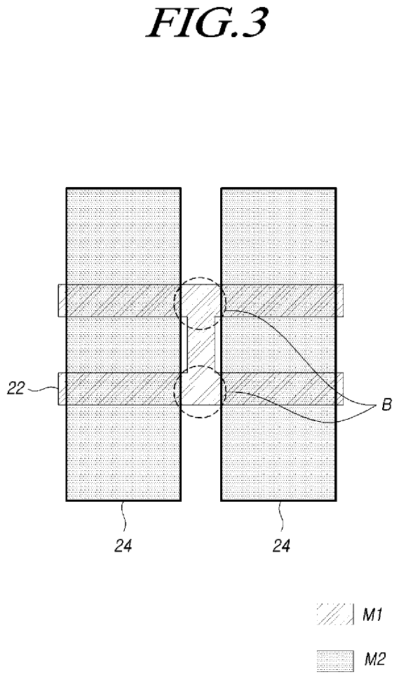

FIG. 1 is a cross-sectional view illustrating an example of a metal wiring of a semiconductor device related to the disclosed technology, FIG. 2 is a plan view illustrating another example of a metal wiring of a semiconductor device related to the disclosed technology, and FIG. 3 is a plan view illustrating still another example of a metal wiring of a semiconductor device related to the disclosed technology.

Referring to FIG. 1, a first dielectric layer 12 may be formed on a substrate 10. Although not illustrated, a device layer including a semiconductor device may be formed on the substrate 10, and the first dielectric layer 12 may be formed on the device layer.

A first metal line 22 may be disposed in a first metal layer M1 on the first dielectric layer 12, a second dielectric layer 14, which covers the first metal line 22, may be formed on the first metal layer M1. A plurality of second metal lines 24 may be disposed in a second metal layer M2 on the second dielectric layer 14.

A process taking place after the second metal layer M2 is formed may be performed in a high-temperature atmosphere. Due to differences in thermal conductivity between the first and second metal lines 22 and 24 and the first and second dielectric layers 12 and 14, heat may be concentrated in a specific portion of the first metal line 22 while performing the process.

For example, as illustrated in FIG. 1, heat is concentrated in a region of first metal line 22 that does not overlap in a vertical direction with second metal line 24.

In the process performed after the second metal layer M2 is formed, the second metal line 24 may serve as a thermal barrier layer to prevent heat from being transferred to a lower portion. Accordingly, in a region where the first metal line 22 overlaps the second metal line 24, the amount of heat transferred to the first metal layer M1 lying below the second metal layer M2 may be reduced. However, in a region where the first metal line 22 does not overlap the second metal line 24, a large amount of heat may be transferred to the first metal layer M1. Therefore, in the region where the first metal line 22 does not overlap the second metal line 24, heat may be concentrated in the first metal line 22 of the first metal layer M1, resulting in voids as illustrated in FIG. 1.

Referring to the plan view of FIG. 2, heat may also be concentrated in a region where first metal lines 22 cross each other, as another example of a region where heat is concentrated.

Heat conducted along first metal lines 22 having a high thermal conductivity may be additive in a region where the first metal lines 22 cross each other. Therefore, heat may be concentrated in the region where the first metal lines 22 cross each other.

In particular, as illustrated in part B of FIG. 3, when both of the above two conditions are satisfied, that is, when a semiconductor device includes a region where the first metal lines 22 cross each other in the first metal layer M1 that is also positioned in the vertical direction under a gap in the overlying second metal line 24, an even greater amount of heat may be concentrated in the region where the first metal lines 22 cross each other.

In the region where heat is concentrated in this way, a void is likely to be formed as metal particles of the first metal line 22 migrate due to the heat. Also, as the first metal line 22 becomes thinner or disconnected due to the presence of voids, defects may occur and the first metal line 22 may not function as a conductor.

Embodiments of the disclosed technology suggest measures capable of preventing wiring defects due to voids by suppressing the generation of voids.

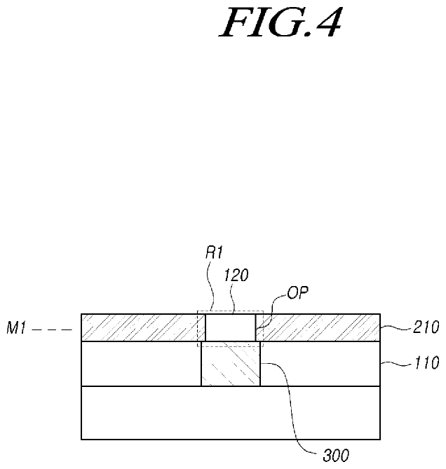

FIG. 4 is a cross-sectional view illustrating a metal wiring of a semiconductor device according to an embodiment of the disclosure.

Referring to FIG. 4, a metal wiring of a semiconductor device may include a first metal line 210 that is disposed in a first metal layer M1, which is in turn disposed on a first dielectric layer 110. The first metal layer M1 has an opening OP in a first region R1. A contact metal 300 extends, from the opening OP and the first metal line 210 around the opening OP in the first region R1, through the first dielectric layer 110.

The first region R1 is a region where heat is concentrated, and the opening OP may be formed in a portion of the first metal line 210 that is removed in the first region R1.

The opening OP may disconnect the first metal line 210. In other embodiments, the opening OP may not disconnect the first metal line 210 or only partially disconnects the first metal line 210.

A dielectric material 120 with a thermal conductivity lower than the first metal line 210 may be disposed in the opening OP.

The contact metal 300 may overlap the opening OP in the vertical direction, and may be directly connected to the opening OP and the first metal line 210 around the opening OP. The contact metal 300 may serve as a conductor in place of the first metal line 210 where the opening OP is formed. That is to say, the first metal line 210 may be replaced functionally with the contact metal 300 at the portion where the opening OP is formed.

Since at least a portion of the first metal line 210 is removed in the first region R1 where heat is concentrated and the edges of the portion where the first metal line 210 are connected by the underlying contact metal 300, even when heat is concentrated in the first region R1, it is possible to suppress voids from being formed in the first metal line 210, and thereby, wiring defects due to voids may be prevented.

Further, since the first metal line 210 is removed in the first region R1 and the dielectric material 120 having a low thermal conductivity is disposed in the portion where the first metal line 210 is removed, the amount of heat introduced into the first region R1 may be reduced.

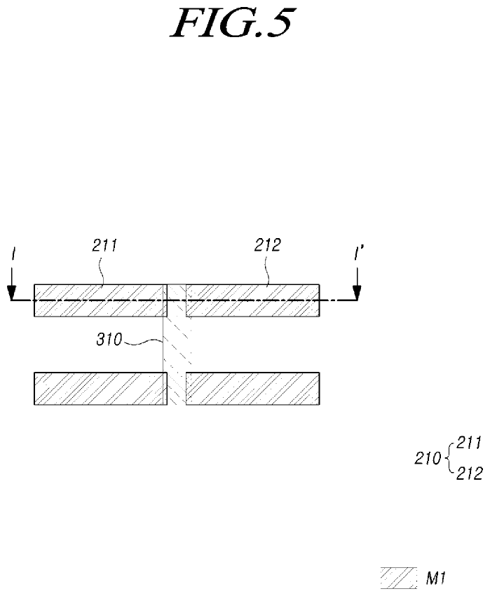

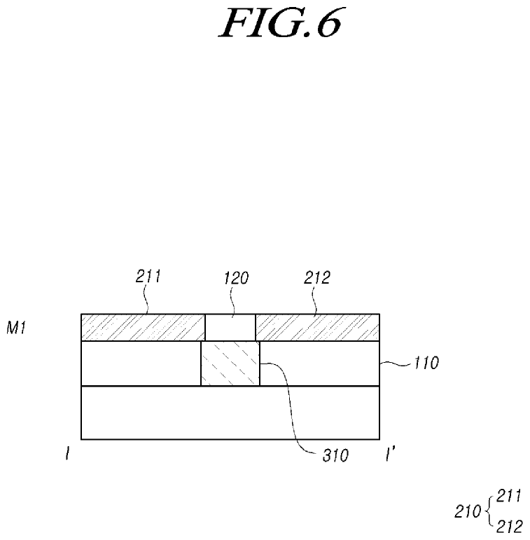

FIG. 5 is a plan view illustrating a metal wiring of a semiconductor device according to another embodiment of the disclosure, and FIG. 6 is a cross-sectional view taken along the line I-I′ of FIG. 5.

Referring to FIGS. 5 and 6, a metal wiring of a semiconductor device may include a first metal line 210 and a contact metal 310, which cross each other in a plan view.

The first metal line 210 may be disposed in a first metal layer M1, and may be divided into two parts by being disconnected in a region where the first metal line 210 crosses the contact metal 310. Hereinbelow, for the sake of convenience in explanation, the two parts of the disconnected first metal line 210 will be defined as a first part 211 and a second part 212.

A dielectric material 120 may be disposed between the first part 211 and the second part 212. The dielectric material 120 may have a thermal conductivity that is lower than the first metal line 210.

The contact metal 310 may pass through the first dielectric layer 110 below the first metal layer M1. From a plan view, in a region where the contact metal 310 and the first metal line 210 cross each other, the contact metal 310 may overlap the first part 211 and the second part 212 of the first metal line 210 in the vertical direction. The contact metal 310 may be directly connected to the first part 211 and the second part 212 at overlapping portions. The contact metal 310 may electrically connect the first part 211 and the second part 212 in the region where the first metal line 210 is disconnected.

FIG. 5 illustrates a contact metal 310 serving as a conductor that connects two parallel first metal lines 210. Although the contact metal 310 crosses the two first metal lines 210 in FIG. 5, embodiments of the disclosed technology are not limited thereto. For example, the contact metal 310 may cross one or at least two first metal lines 210.

As described above with reference to FIG. 2, when the first metal lines 22 of the first metal layer M1 cross each other or are otherwise connected, heat conducted along the first metal lines 22 having a high thermal conductivity may be summed at the region where the first metal lines 22 cross each other. Therefore, heat may be concentrated in the region where the first metal lines 22 cross each other.

Referring back to FIGS. 5 and 6, in embodiments of the disclosure, the first metal lines 210 are disconnected, resulting in a first part 211 and a second part 212 of the first metal lines 210. The crossing metal line illustrated in FIG. 2 is replaced with an underlying contact metal 310. As a consequence, it is possible to prevent heat from being concentrated in the region where the contact metal 310 and the first metal line 210 cross each other in a plan view, and it is possible to suppress voids from being formed in the first metal line 210. As a result, wiring defects due to voids can be prevented.

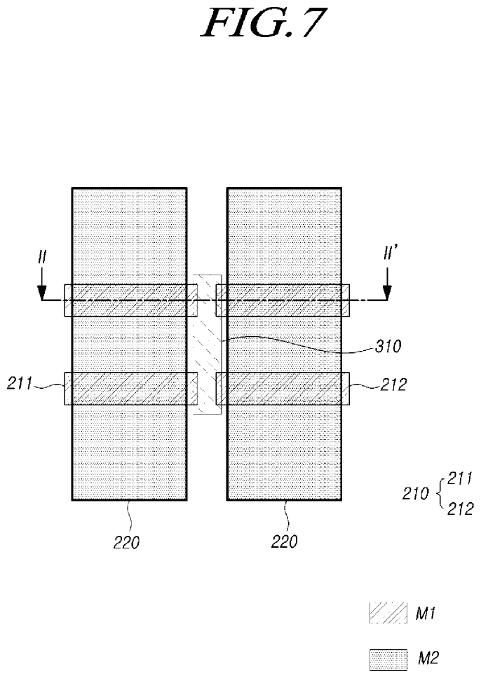

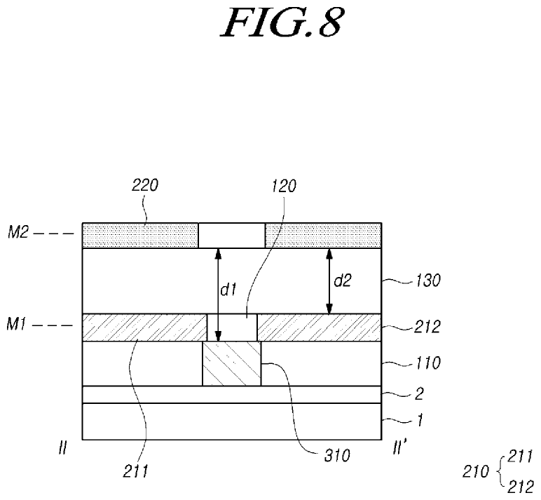

FIG. 7 is a plan view illustrating a metal wiring of a semiconductor device according to another embodiment of the disclosure, and FIG. 8 is a cross-sectional view taken along the line II-II′ of FIG. 7.

Referring to FIGS. 7 and 8, a device layer 2 including a semiconductor device may be formed on a substrate 1.

The semiconductor device may be various types of individual devices for configuring, for example, a dynamic random access memory (DRAM), a static random access memory (SRAM), a flash memory, an is electrically erasable and programmable read only memory (EEPROM), a phase change random access memory (PRAM), a magnetic random access memory (MRAM), a resistive random access memory (RRAM), a central processing unit (CPU), a graphic processing unit (GPU) or an application processor (AP). Types of semiconductor devices are not limited to the above examples, and any type of a semiconductor device using a metal wiring is possible.

A first dielectric layer 110 may be formed on the device layer 2, a first metal line 210 may be disposed in a first metal layer M1 on the first dielectric layer 110, a second dielectric layer 130 that covers the first metal line 210 may be formed on the first metal layer M1, and a second metal line 220 may be disposed in a second metal layer M2 on the second dielectric layer 130.

The first and second metal lines 210 and 220 may be electrically connected to a semiconductor device. Typically, the first metal line 210 of the underlying first metal layer M1 is narrower and thinner than the second metal line 220 of the overlying second metal layer M2. Accordingly, the first metal line 210 may be vulnerable to defects due to voids when compared to the second metal line 220.

Since the second metal line 220 serves as a thermal barrier layer in processes performed after the second metal layer M2 is formed, the amount of heat transferred to the first metal layer M1 in a region where the first metal line 210 overlaps the second metal line 220 in the vertical direction is not large. On the other hand, in a region where the first metal line 210 does not overlap the second metal line 220 in the vertical direction, a large amount of heat may be transferred to the first metal layer M1. Embodiments of the disclosure improve such wiring structures.

Referring back to FIG. 8, a first metal line 210 may be disconnected in a region where the first metal line 210 does not overlap the second metal line 220. As a result, referring to FIG. 7, the first metal line 210 to be divided into a first part 211 and a second part 212.

A dielectric material 120 may be disposed in the region where the first metal line 210 is disconnected. The dielectric material 120 may have a thermal conductivity that is lower than the first metal line 210.

The contact metal 310 may be in contact with the first part 211 and the second part 212, and may serve as a conductor that electrically connects the first part 211 and the second part 212 of the first metal line 210 in the region where the first metal line 210 does not overlap the second metal line 220. In other words, in the region where the first metal line 210 does not overlap the second metal line 220, at least a portion of the first metal line 210 may be replaced with the contact metal 310.

The contact metal 310 may be disposed under the first metal layer M1. Therefore, a first distance d1 between the contact metal 310 and the second metal layer M2 is greater than a second distance d2 between the first metal layer M1 and the second metal layer M2. The contact metal 310 may be configured to pass through the first dielectric layer 110 immediately under the first metal layer M1. In this case, the difference between the first distance d1 and the second distance d2 may be substantially the same as the thickness of the first metal layer M1.

For example, the contact metal 310 may have a line shape that crosses, from a plan view, the first metal line 210 in a region including the region where the first metal line 210 is disconnected. In a region where the contact metal 310 crosses the first metal line 210, the contact metal 310 may vertically overlap the first part 211 and the second part 212 of the first metal line 210, and may be directly connected to the first part 211 and the second part 212 at overlapping portions.

FIG. 7 illustrates a single contact metal 310 connecting first and second parts of two first metal lines 210. Although the contact metal 310 crosses the two first metal lines 210 in FIG. 7, embodiments of the disclosed technology are not limited thereto. The contact metal 310 may cross one or at least two first metal lines 210.

According to embodiments of the disclosed technology, the second metal line 220 cannot serve as a thermal barrier layer where the first metal line 210 does not overlap the second metal line 220 in the vertical or stack direction. By replacing the first metal line 210 with the underlying contact metal 310 in the region where the first metal line 210 does not overlap the second metal line 220, it is possible to is prevent overheating concentrated on a specific portion of the first metal line 210 in subsequent processes after the second metal line 220 is formed. As a result, it is possible to suppress voids from being formed in the first metal line 210, and thereby, to prevent wiring defects due to voids.

The above-described metal wiring may be applied to various memory modules and electronic systems.

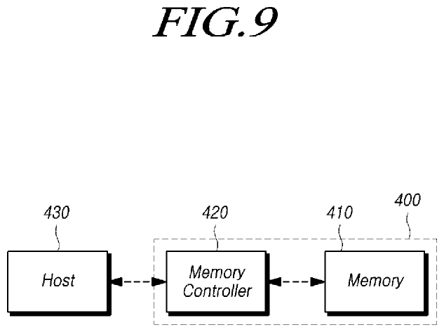

FIG. 9 is a block diagram of a memory card including a metal wiring according to an embodiment of the disclosure.

Referring to FIG. 9, a memory 410 including a metal wiring may be applied to a memory card 400. For example, the memory card 400 may include the memory 410 in the form of a nonvolatile memory device and a memory controller 420. The memory 410 and the memory controller 420 may store data or read stored data.

The memory controller 420 controls the memory 410 to read stored data or store data in response to a read/write request from a host 430.

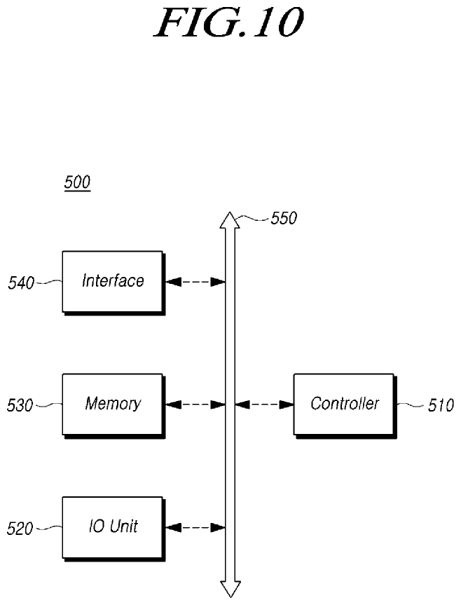

FIG. 10 is a block diagram of an electronic system to which a semiconductor device including a metal wiring according to an embodiment of the disclosure is applied.

Referring to FIG. 10, an electronic system 500 may include a memory 530 including a semiconductor device that has a metal wiring based on an embodiment of the disclosed technology. The electronic system 500 may include a controller 510, an input/output unit 520, and the memory 530. The controller 510, the input/output unit 520 and the memory 530 may be electrically coupled with one another through a bus 550, which provides a data movement path.

For example, the controller 510 may include at least one microprocessor, at least one digital signal processor, at least one microcontroller, and at least one of logic circuits capable of performing the same functions as these components. The memory 530 may include a semiconductor device that has the metal wiring according to embodiments of the disclosure. The input/output unit 520 may include at least one selected among a keypad, a keyboard, a display device, a touch screen, and so forth. The memory 530 as a device for storing data may store data or/and commands to be executed by the controller 510 or the like.

The memory 530 may include a volatile memory device such as a DRAM and/or a nonvolatile memory device such as a flash memory. For example, a flash memory may be mounted to an information processing system such as a mobile terminal or a desk top computer. The flash memory may be configured as a solid state drive (SSD). In this case, the electronic system 500 may stably store a large amount of data in a flash memory system.

The electronic system 500 may further include an interface 540, which is set to be able to transmit and receive data to and from a communication network. The interface 540 may be a wired or wireless type. For example, the interface 540 may include an antenna, a wired transceiver or a wireless transceiver.

The electronic system 500 may be understood as a mobile system, a personal computer, a computer for an industrial use or a logic system which performs various functions. For example, the mobile system may be any one among a personal digital assistant (PDA), a portable computer, a tablet computer, a mobile phone, a smart phone, a wireless phone, a laptop computer, a memory card, a digital music system and an information transmission/reception system.

Where the electronic system 500 is a device capable of performing wireless communication, the electronic system 500 may be used in a communication system such as CDMA (code division multiple access), GSM (global system for mobile communications), NADC (north American digital cellular), E-TDMA (enhanced-time division multiple access), WCDMA (wideband code division multiple access), CDMA2000, LTE (long term evolution) and Wibro (wireless broadband Internet).

Although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted is in connection with the appended claims and encompass all equivalents falling within the scope of the appended claims.

What is claimed is:

1. A metal wiring of a semiconductor device, comprising:
a first metal line disposed in a first metal layer, and having an opening in a first region; and
a contact metal passing through a dielectric layer under the first metal layer adjacent to the opening and connected to the first metal line around the opening.

2. The metal wiring of a semiconductor device according to claim 1, wherein the first region is a region where heat is concentrated.

3. The metal wiring of a semiconductor device according to claim 1, wherein
the contact metal has a line shape that crosses the first metal line when viewed on the top, and
the first region is a region where the first metal line and the is contact metal cross each other when viewed on the top.

4. The metal wiring of a semiconductor device according to claim 1, wherein the first region is a region where the first metal layer does not overlap, in a vertical direction, a metal line disposed in a second metal layer.

5. The metal wiring of a semiconductor device according to claim 1, wherein a dielectric material that has a thermal conductivity lower than the first metal line is disposed in the opening.

6. A metal wiring of a semiconductor device, comprising:
a first metal line disposed in a first metal layer and disconnected in a first region; and
a contact metal passing through a first dielectric layer under the first metal layer, crossing the first metal line in the first region in a vertical direction, and connecting disconnected ends of to the first metal line.

7. The metal wiring of a semiconductor device according to claim 6, wherein a dielectric material that has a thermal conductivity lower than the first metal line is disposed between disconnected ends of the first metal line.

8. A metal wiring of a semiconductor device, comprising:
a first metal line disposed in a first metal layer, disconnected in a region where the first metal line does not overlap a metal line of a second metal layer in a vertical direction, and divided into a first part and a second part; and
a contact metal connecting the first part and the second part,
wherein a first distance in the vertical direction between the second metal layer and the contact metal is greater than a second distance between the second metal layer and the first metal layer.

9. The metal wiring of a semiconductor device according to claim 8, wherein a difference between the first distance and the second distance is the same as a thickness of the first metal layer.

10. The metal wiring of a semiconductor device according to claim 8, wherein the contact metal has a line shape that crosses the first metal line when viewed on the top.
